(19) United States
(12) Patent Application Publication
(10) Pub. No.: US 2020/0388576 A1
(43) Pub. Date: Dec. 10, 2020

(54) LAYER FOR ETCHED IDENTIFICATION MARKS ON A PACKAGE

(71) Applicant: Intel Corporation, Santa Clara, CA (US)

(72) Inventors: Taylor GAINES, Chandler, AZ (US); Kosuke HIROTA, Portland, OR (US); Yoshihiro TOMITA, Tsukuba-shi (JP); Jimin YAO, Chandler, AZ (US)

(21) Appl. No.: 16/436,576

(22) Filed: Jun. 10, 2019

(51) Int. Cl. H01L 23/544; H01L 23/367; H01L 23/552; H01L 21/78; B23K 26/362

(52) U.S. Cl. CPC H01L 23/544; H01L 23/367; H01L 2223/54433; H01L 21/78; B23K 26/362; H01L 23/552

(57) ABSTRACT

Embodiments herein relate to systems, apparatuses, or processes for a layer for etched identification marks on a package. Embodiments include applying a layer to a side of a package, and laser etching the layer with an identification mark associated with the package to provide a visible identification on the package. In particular, the layer may be an EMI shielding layer of film laminate applied to the side of the package to protect the package from EMI or to protect surrounding components from EMI generated by the package. A laser or some other etching technique may then be performed on the layer to make a visible identification on the package.

### FIELD

Embodiments of the present disclosure generally relate to the field of package assemblies, and in particular package assemblies that include etched identification marks.

### BACKGROUND

Continued reduction in end product size of mobile electronic devices such as smart phones and ultrabooks is a driving force for the development of reduced size package components that include visual labels.

### BRIEF DESCRIPTION OF THE DRAWINGS

FIG. 1 illustrates legacy examples of cross-sections of a spray and a sputter film applied to a side of a package, in accordance with embodiments.

FIGS. 2A-2C illustrate an example of top-down images of a spray and a sputter film applied to a side of a package, and a cross-section of a film laminate applied to a side of a package, in accordance with embodiments.

FIG. 3 illustrates a diagram of a portion of the wafer with two packages coated with a layer, in accordance with embodiments.

FIGS. 4A-4D illustrate an example of a package assembly with a film applied to a side of the package at various stages of a manufacturing process, in accordance with embodiments.

FIG. 5 illustrates an example of a number of packages with various depths of laser marking on the package, in accordance with embodiments.

FIG. 6 illustrates an example of a process to apply an electromagnetic interference (EMI) shielding layer on a side of a package for subsequent laser etching, in accordance with embodiments.

FIG. 7 schematically illustrates a computing device, in accordance with embodiments.

### DETAILED DESCRIPTION

Embodiments of the present disclosure may generally relate to systems, apparatus, and/or processes directed to applying a layer to a side of a package, and laser etching the layer with an identification mark associated with the package to provide a visible identification of the package. In particular, the layer may be an EMI shielding layer applied to the side of the package to protect the package from EMI or to protect surrounding components from EMI generated by the package. Once the EMI shielding layer is in place, a laser or some other etching technique may be performed to make a visible identification mark on the package.

In embodiments, the layer may include a sheet, such as a graphite sheet, that is laminated to the package, for example at the strip level. In other embodiments, the layer may be a sprayed or a sputtered coating applied to the package. After the layer hardens or cures, the layer provides a surface onto which a laser etching technique may be applied to mark an identification on the package. This laser etching technique may be also referred to as laser marking.

In legacy implementations, EMI shielding is sprayed or sputtered onto a package after the package has been laser marked. As a result, the laser mark may be filled in after the EMI shielding is applied, reducing or in some cases completely filling the indentations of the laser mark to render the laser mark difficult or impossible to visually identify.

In legacy implementations, sputtering the EMI shielding may provide better readability of a laser mark, however there are difficulties with this approach. The size of the sputtering tools used are very large, expensive, and may substantially slow package production run rates. For example, the cost may be in the millions for each tool, and the run time to apply the sputter may be minutes per wafer onto which packages may be manufactured. For example, the legacy techniques may include drawing a vacuum around the wafer, and applying bake and plasma techniques.

TABLE 1

| | Ion-Gun | | SUS | | Cu | | SUS | |
|---|---|---|---|---|---|---|---|---|
| Drum | 10 rpm | | | | | | | |
| rotation | | | | | | | | |
| Film | 50 | nm | 0.3 | μm | 4.0 | μm | 0.3 | μm |
| thickness | | | | | | | | |
| Power | 2.4 | kV | 23 | kW | 15 | kWx2 | 23 | kW |
| Air Flow | 50 | sccm | 100 | sccm | 140 | sccm | 100 | sccm |
| Pressure | 0.2 | Pa | 0.9 | Pa | 1.2 | Pa | 0.9 | Pa |
| Time | 930 | sec | 122 | sec | 602 | sec | 122 | sec |

Table 1 shows various aspects of detail process conditions in accordance with embodiments.

As a result, legacy techniques makes it difficult to process large volumes of, for example, mobile phone or flip-chip chip scale package (FCCSP) packages. Using a spray technique results in a higher material cost. In addition, reading laser marks on packages after a spray technique is applied may require changes to light attributes. This may include changing the angle and requiring coaxial light for readability. In addition, the techniques require reconstitution of the singulated package onto a ball grid array (BGA) protection solution. This may require extra cost for material, lamination tools, the addition of a removal step, and wafer or strip cleaning after applying the spray or sputter.

Embodiments described herein may be directed to laminating a sheet, such as a graphite sheet for EMI protection, to one or more packages at the wafer or strip level, and then applying laser marking to the laminate on the one or more packages. Other embodiments may be directed to applying a sputter or a spray, for EMI protection, to the one or more packages at the strip level and then applying laser marking to the cured coating on the one or more packages.

These techniques provide benefits over legacy implementations. These techniques may be performed with existing tooling at the strip level. For example, mold tooled for pressing film, current singulation tools, and/or laser mark tools. In addition, no reconstitution onto expensive films, no removal of films, nor cleaning tools for the residue are required. Also, if side wall EMI shielding, perpendicular to the top surface of the package, is needed, partial cuts (trenches) and printing of a metal-filled EMI paste can be performed with existing tools. In addition, these techniques will also provide a clear thermal benefit (Z˜13 watts per meter-kelvin of thermal conductivity (W/mk), XY˜1600 W/mk).

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

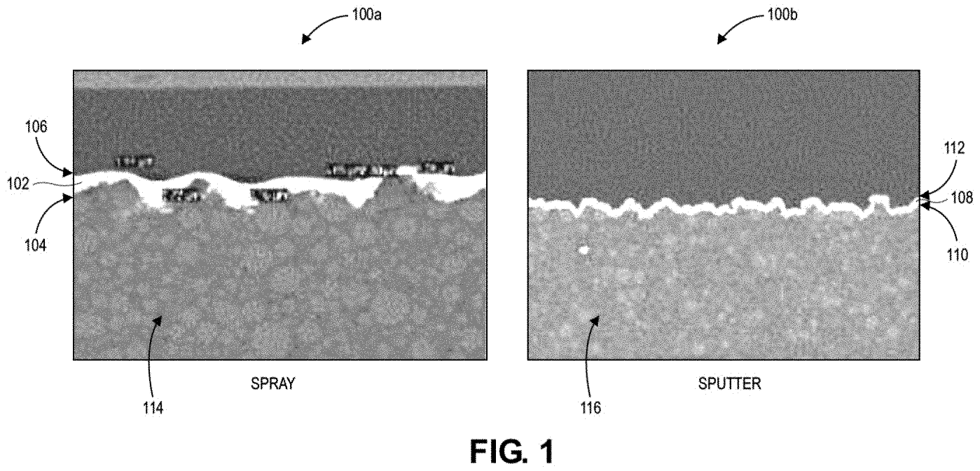

FIG. 1 illustrates legacy examples of cross-sections of a spray and a sputter film applied to a side of a package, in accordance with embodiments. Diagram 100a shows an example cross-section of a package 114 that has a first side 104 onto which a spray coating 102 has been applied by using a spraying technique. In this example, the coating is an EMI protective coating having a top layer 106. As shown, the top layer 106 of the spray coating 102 is substantially smoother than first side 104 of the package 114. Thus, if the first side 104 includes laser etching to place identification marks, or laser marks, on the package 114, then applying a spray coating 102 will tend to fill in the etching and obscure the identification marks from view. Even the thinnest sintering spray materials sufficient for EMI protective shielding may result in a 30% reduction in readability of the identification mark.

Diagram 100b shows an example cross-section of the package 116 that has a first side 110 onto which a sputtered coating 108 has been applied using a sputtering technique. In this example, the coating is an EMI protective coating, having a top layer 112. As shown, the top layer 112 of the sputtered coating 108 roughly parallels the contour of the first side 110, with a slight smoothing of the surface. As shown, sputtering typically allows laser mark readability after the sputtering process technique is applied over the package 116.

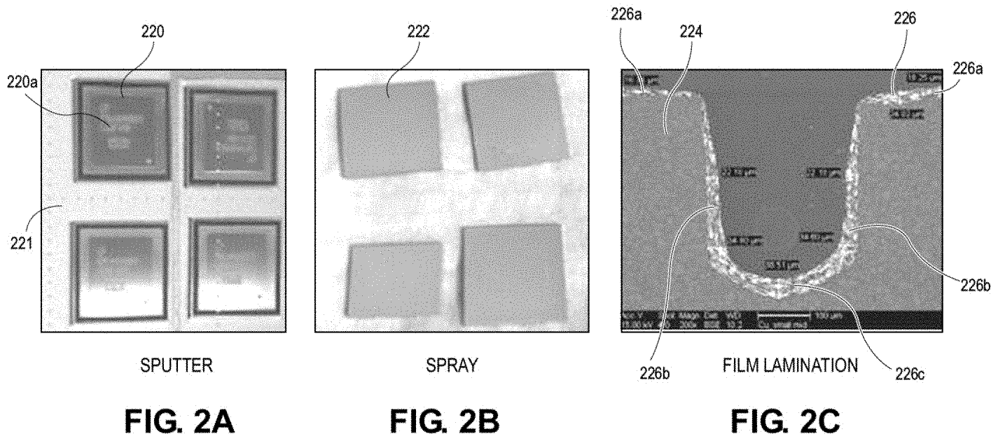

FIGS. 2A-2C illustrate an example of top-down images of a spray and a sputter film applied to a side of a package, and a cross-section of a film laminate applied to a side of a package, in accordance with embodiments. FIG. 2A shows an example of a top-down photograph of four packages 220 that have a laser mark 220a applied to each of the packages 220. After the application of the laser mark 220a, an EMI protective shielding 221 was sputtered onto each of the packages 220. As shown, the laser mark 220a is visible through the sputtered EMI protective shielding 221.

FIG. 2B shows an example of a top-down photograph of four packages 222 that have a laser mark (not shown) applied to each of the packages 222. After the application of the laser mark (not shown) and EMI protective shielding was sprayed onto each of the packages 222. As shown, no laser mark is visible through the sprayed EMI protective shielding because the spraying technique filled in the laser marks. Thus, there is no visual identification for any of the packages 222 where the spray technique is used.

FIG. 2C shows a cross-section of the film laminate 226 applied to each of packages 224, according to embodiment. As shown, the film laminate 226 is able to provide adequate EMI protective shielding at a top of the packages 226a, as well as to sides of the packages 226b, as well as to an area between the packages 226c.

In embodiments, the film laminate 226 may be a graphite sheet covering the packages 224 prior to simulation. In embodiments, using a graphite sheet which is film laminate 226 may not only provide EMI protective shielding, but also be used for thermal performance.

In embodiments, an adhesive (not shown) may be first applied to the packages 224 to facilitate adherence to the film laminate 226. In embodiments, the adhesive may be used to facilitate adherence when applying the film laminate 226 to silicon or to a mold compound. In embodiments, the adhesive may be sputtered or sprayed onto the packages 224 prior to singulation and application of the film laminate 226.

In embodiments, the film laminate 226 may be a graphite only film, or may be a film with a certain percentage of graphite for EMI shielding. In embodiments, the film may be a polymer resin matrix with graphite particles dispersed within the matrix. In embodiments, the film laminate may include silver, copper, carbon, or graphite, or any combination thereof.

TABLE 2
Table of Electrical Resistivity/Conductivity
at 20° C. to Provide an Effective EMI Shield

| | ρ (Ω · m) at 20° C. | σ (S/m) at 20° C. |
|---|---|---|
| Material | Resistivity | Conductivity |
| Silver | 1.59 × 10−8 | 6.30 × 107 |
| Copper | 1.68 × 10−8 | 5.96 × 107 |
| Gold | 2.44 × 10−8 | 4.10 × 107 |
| Stainless steel | 6.9 × 10−7 | 1.45 × 106 |
| Carbon | 2.5 × 10−6 to | 2 to 3 × 105 // basal plane |
| | 5.0 × 10−6 // basal plane | |
| (graphite) | 3.0 × 10−3 ⊥basal plane | 3.3 × 102 ⊥basal plane |

Table 2 shows various aspects of film laminate. In embodiments, the film laminate 226 is thick enough for a laser etching technique to be applied to provide visual identification for each of the packages 224. In addition, the thickness and/or composition of the film laminate 226 should take into account thinning in the areas where the laser etching is applied to the film laminate 226 to not alter required EMI properties.

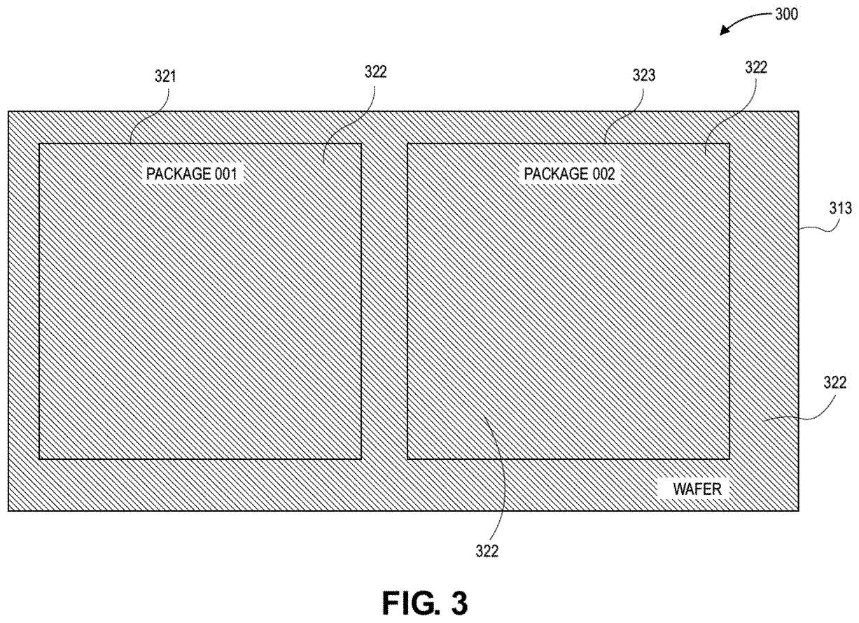

FIG. 3 illustrates a diagram of a portion of the wafer with two packages coated with a layer, in accordance with embodiments. Diagram 300 shows a top-down view of a wafer strip 313 that includes two packages 321, 323, which may be similar to packages 220, 222, 224 of FIGS. 2A-2C. As shown, the wafer strip 313 and the packages 321, 323 are coated in a film laminate 322, which may be similar to film laminate 226 of FIG. 2C, that provides EMI protective shielding to the packages 321, 323. Subsequent to the application of the film laminate 322, etching for the packages (not shown, but similar to 220a of FIG. 2A), may then be applied on top of the film laminate 322 prior to singulation. As described above, the film laminate 322 may be a graphite sheet, which may be then laser marked to provide a visual identification of each of the packages 321, 323.

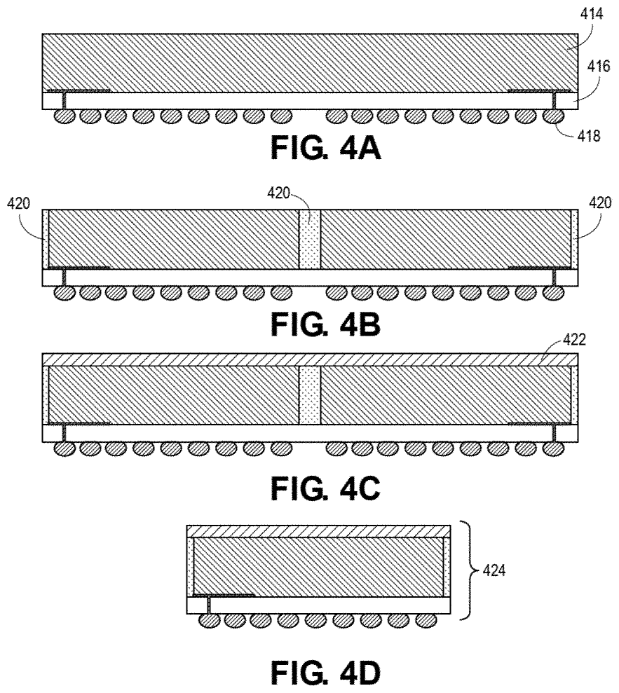

FIGS. 4A-4D illustrate an example of a package assembly with a film applied to a side of the package at various stages of a manufacturing process, in accordance with embodiments. In embodiments, each of the stages may be performed using legacy toolsets. At FIG. 4A, a portion of packages 414 maybe physically and/or electrically coupled with a substrate 416. The substrate 416 may be physically and/or electrically coupled with a BGA 418. A top of the portion of the package 414, as shown, may be ground or partially ground to achieve a planar surface.

At FIG. 4B, trenches 420 may be produced to separate the packages 414. In embodiments, this may be done to allow sidewall shielding of the packages 414. As shown, an EMI paste may be applied to the trenches 420 to provide sidewall EMI shielding after singulation. This may be accomplished through a trench print technique.

At FIG. 4C, a film laminate 422, which may be similar to the film laminate 322 of FIG. 3, or film laminate 226 of FIG. 2C, may be applied to the top of packages 414. In embodiments where EMI paste is applied to the trenches 420, the film laminate 422 will be applied across the filled trenches 420 once the EMI paste is cured. In embodiments, an adhesive (not shown) may be applied prior to the application of the film laminate 422. In embodiments, graphite sheets with acrylic adhesives may be used as film laminate 422. In embodiments where trenches 420 are not filled with a paste, the film laminate 422 may be drawn down into the trench 420, providing sidewall shielding of the packages 414, similar to film laminate 226b of FIG. 2C. Laser marking or some other etching technique may be used in the film laminate 422 after application to visually identify the packages 414. For example, a green laser may be used to apply a laser mark.

FIG. 4D, shows a package 424 after singulation that has EMI shielding around the top and sides of the package. The laminate and paste materials may include any type of graphite and any type of adhesive or filled-adhesive that could be used to bond the laminate to the package. Adhesives may include epoxies, acrylics, acrylates, silicones, polyurethanes, 2-part adhesives, and the like. Fillers within the film laminate or adhesives may include conductive and non-conductive fillers. The selection of filler may depend upon mechanical, thermal, processing and reliability impacts. A package 424 may include a FCCSP, wirebond, or other molded package, glob top package, mobile-type packages including system in package (SIP), but are not limited to these types of packages.

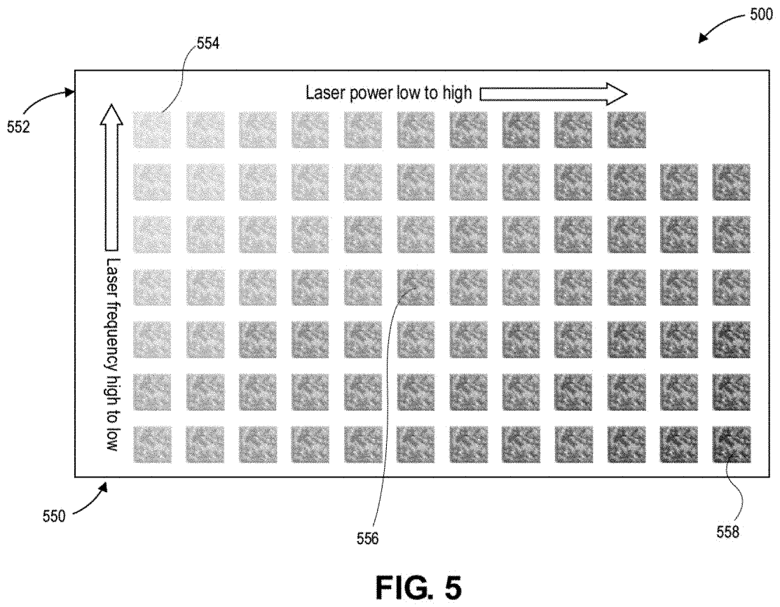

FIG. 5 illustrates an example of a number of packages with various depths of laser marking on the package, in accordance with embodiments. Diagram 500 includes images of different laser markings on a laminated graphite-acrylic adhesive sheet. The top row 552 includes column numbers that indicate laser power used for the marking, and the left column 550 includes row numbers that indicate laser frequency used for marking. For example, a first sample 554 shows the mark created using the low power and low frequency laser. A second sample 556 shows the mark created using the middle power and middle frequency range laser. A third sample shows 558 the mark created using the high power and high frequency laser. FIG. 5 shows that the laser mark quality is good within a wide range of laser setting conditions.

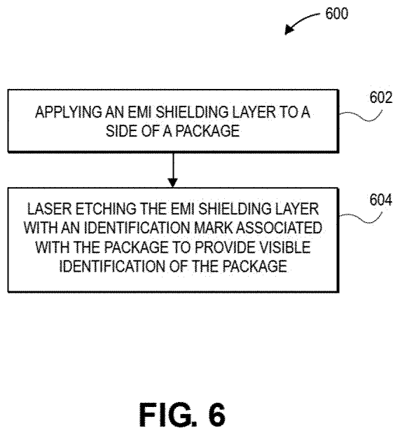

FIG. 6 illustrates an example of a process to apply an electromagnetic interference (EMI) shielding layer on a side of a package for subsequent laser etching, in accordance with embodiments. The process 600 may be implemented by one or more of the techniques as shown and/or described with respect to FIGS. 1, 2A-2C, 3, 4A-4C, and 5.

At block 602, the process may include applying an EMI shielding layer to a side of the package. In embodiments, the EMI shielding layer may include the film laminate 226 of FIG. 2C, 322 of FIG. 3, 422 of FIG. 4C, or as shown as part of diagram 500 of FIG. 5. In embodiments, the package may be similar to package 220, 222, 224 of FIG. 2A-2C, 321, 323 of FIG. 3, or 414 of FIG. 4A. In embodiments, the shielding layer may be sputtered on as shown with respect to FIG. 2A, sprayed on, as shown with respect to FIG. 2B, or a film laminated on as shown with respect to FIG. 2C. In embodiments, film layer may be preceded by an adhesive layer applied to the side of the package. In embodiments, the film layer may include particles of graphite, silver, copper, or other particle used to provide EMI shielding.

At block 604, the process may include laser etching the EMI shielding layer with an identification mark associated with the package to provide visible identification of the package. In embodiments, laser etching may be similar to etching 220a of FIG. 2A on the shielding layer such as shielding layer 226 of FIG. 2C or 322 of FIG. 3, or 422 of FIG. 4C. In embodiments, the etching may be done by a green laser, or some other laser having a characteristic suitable for etching into the shielding layer. In embodiments, different depths of etching may be used, such as described with respect to diagram 500 of FIG. 5.

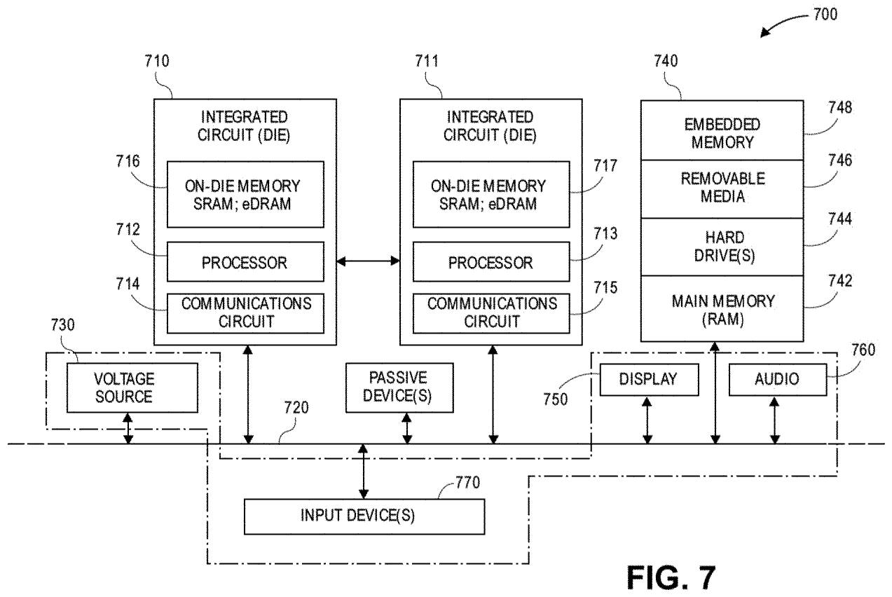

FIG. 7 schematically illustrates a computing device, in accordance with embodiments. The computer system 700 (also referred to as the electronic system 700) as depicted can embody a layer for etched identification marks on a package, according to any of the several disclosed embodiments and their equivalents as set forth in this disclosure. The computer system 700 may be a mobile device such as a netbook computer. The computer system 700 may be a mobile device such as a wireless smart phone. The computer system 700 may be a desktop computer. The computer system 700 may be a hand-held reader. The computer system 700 may be a server system. The computer system 700 may be a supercomputer or high-performance computing system.

In an embodiment, the electronic system 700 is a computer system that includes a system bus 720 to electrically couple the various components of the electronic system 700. The system bus 720 is a single bus or any combination of busses according to various embodiments. The electronic system 700 includes a voltage source 730 that provides power to the integrated circuit 710. In some embodiments, the voltage source 730 supplies current to the integrated circuit 710 through the system bus 720.

The integrated circuit 710 is electrically coupled to the system bus 720 and includes any circuit, or combination of circuits according to an embodiment. In an embodiment, the integrated circuit 710 includes a processor 712 that can be of any type. As used herein, the processor 712 may mean any type of circuit such as, but not limited to, a microprocessor, a microcontroller, a graphics processor, a digital signal processor, or another processor. In an embodiment, the processor 712 includes, or is coupled with, a layer for etched identification marks on a package, as disclosed herein. In an embodiment, SRAM embodiments are found in memory caches of the processor. Other types of circuits that can be included in the integrated circuit 710 are a custom circuit or an application-specific integrated circuit (ASIC), such as a communications circuit 714 for use in wireless devices such as cellular telephones, smart phones, pagers, portable computers, two-way radios, and similar electronic systems, or a communications circuit for servers. In an embodiment, the integrated circuit 710 includes on-die memory 716 such as static random-access memory (SRAM). In an embodiment, the integrated circuit 710 includes embedded on-die memory 716 such as embedded dynamic random-access memory (eDRAM).

In an embodiment, the integrated circuit 710 is complemented with a subsequent integrated circuit 711. Useful embodiments include a dual processor 713 and a dual communications circuit 715 and dual on-die memory 717 such as SRAM. In an embodiment, the dual integrated circuit 710 includes embedded on-die memory 717 such as eDRAM.

In an embodiment, the electronic system 700 also includes an external memory 740 that in turn may include one or more memory elements suitable to the particular application, such as a main memory 742 in the form of RAM, one or more hard drives 744, and/or one or more drives that handle removable media 746, such as diskettes, compact disks (CDs), digital variable disks (DVDs), flash memory drives, and other removable media known in the art. The external memory 740 may also be embedded memory 748 such as the first die in a die stack, according to an embodiment.

In an embodiment, the electronic system 700 also includes a display device 750, an audio output 760. In an embodiment, the electronic system 700 includes an input device such as a controller 770 that may be a keyboard, mouse, trackball, game controller, microphone, voice-recognition device, or any other input device that inputs information into the electronic system 700. In an embodiment, an input device 770 is a camera. In an embodiment, an input device 770 is a digital sound recorder. In an embodiment, an input device 770 is a camera and a digital sound recorder.

As shown herein, the integrated circuit 710 can be implemented in a number of different embodiments, including a package substrate having a layer for etched identification marks on a package, according to any of the several disclosed embodiments and their equivalents, an electronic system, a computer system, one or more methods of fabricating an integrated circuit, and one or more methods of fabricating an electronic assembly that includes a package substrate having a layer for etched identification marks, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a layer for etched identification marks on a package embodiments and their equivalents. A foundation substrate may be included, as represented by the dashed line of FIG. 7. Passive devices may also be included, as is also depicted in FIG. 7.

### EXAMPLES

The following paragraphs describe examples of various embodiments.

Example 1 is an apparatus comprising: a package; a layer coupled to a side of the package, wherein an identification mark associated with the package is etched into the layer to provide a visible identification on the package.

Example 2 includes the apparatus of example 1, wherein the layer is an electromagnetic interference (EMI) shielding layer to protect the package from EMI.

Example 3 includes the apparatus of example 1, wherein the layer is a thermal insulating layer to alter thermal conductivity of the package.

Example 4 includes the apparatus of example 1, wherein the layer is a laminated sheet applied to the side of the package.

Example 5 includes the apparatus of example 4, wherein an adhesive material is positioned between the side of the package and the layer to secure the layer onto the package.

Example 6 includes the apparatus of example 4, wherein the layer is a metal-filled film.

Example 7 includes the apparatus of example 4, wherein the layer includes a polymer resin matrix or acrylic.

Example 8 includes the apparatus of example 7, wherein the EMI-blocking material within the matrix or acrylic includes a selected one of silver, copper, or graphite.

Example 9 includes the apparatus of example 1, wherein the layer is sprayed or sputtered onto the side of the package.

Example 10 includes the apparatus of example 9, wherein the layer includes a polymer resin matrix with EMI-blocking material within the matrix, wherein the EMI-blocking material includes a selected one of silver, copper, or graphite.

Example 11 includes the apparatus of example 9, further including an adhesive material position between the side of the package and the layer.

Example 12 is a system comprising: a package, including a layer coupled to a side of the package, wherein an identification mark associated with the package is etched into the layer to provide a visible identification of the package; and a substrate electrically or physically coupled with the package.

Example 13 includes the system of example 12, wherein the layer is an electromagnetic interference (EMI) shielding layer to protect the package from EMI.

Example 14 includes the system of example 12, wherein the side of the package includes silicon or a molding compound.

Example 15 includes the system of example 12, wherein the layer is a laminated sheet applied to the side of the package.

Example 16 includes the system of example 15, wherein an adhesive material is positioned between the side of the package and the layer to secure the layer onto the package.

Example 17 includes the system of example 15, wherein the layer is a metal-filled film.

Example 18 includes the system of claim 15, wherein the layer includes a polymer resin matrix or acrylic, wherein the layer includes EMI-blocking material within the matrix or acrylic that includes a selected one of silver, copper, or graphite.

Example 19 includes the system of example 12, wherein the layer is sprayed or sputtered onto the side of the package.

Example 20 includes the system of example 19, further including an adhesive material position between the side of the package and the layer.

Example 21 is a method comprising: applying an electromagnetic interference (EMI) shielding layer to a side of a package; and laser etching the EMI shielding layer with an identification mark associated with the package to provide visible identification of the package.

Example 22 includes the method of example 21, further comprising applying an adhesive layer to the side of the package prior to applying the EMI shielding layer to secure the shielding layer onto the package.

Example 23 includes the method of example 21, wherein applying an EMI shielding layer further includes applying a laminated sheet, or spraying or sputtering the layer onto the side of the package.

Example 24 includes the method of claim 21, wherein the EMI shielding layer includes a polymer resin matrix or an acrylic.

Example 25 includes the method of claim 21, wherein the EMI shielding layer includes a selected one of silver, copper, or graphite.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. An apparatus comprising:
a package;
a layer coupled to a side of the package, wherein an identification mark associated with the package is etched into the layer to provide a visible identification on the package.

2. The apparatus of claim 1, wherein the layer is an electromagnetic interference (EMI) shielding layer to protect the package from EMI.

3. The apparatus of claim 1, wherein the layer is a thermal insulating layer to alter thermal conductivity of the package.

4. The apparatus of claim 1, wherein the layer is a laminated sheet applied to the side of the package.

5. The apparatus of claim 4, wherein an adhesive material is positioned between the side of the package and the layer to secure the layer onto the package.

6. The apparatus of claim 4, wherein the layer is a metal-filled film.

7. The apparatus of claim 4, wherein the layer includes a polymer resin matrix or acrylic.

8. The apparatus of claim 7, wherein the EMI-blocking material within the matrix or acrylic includes a selected one of silver, copper, or graphite.

9. The apparatus of claim 1, wherein the layer is sprayed or sputtered onto the side of the package.

10. The apparatus of claim 9, wherein the layer includes a polymer resin matrix with EMI-blocking material within the matrix, wherein the EMI-blocking material includes a selected one of silver, copper, or graphite.

11. The apparatus of claim 9, further including an adhesive material position between the side of the package and the layer.

12. A system comprising:
a package, including a layer coupled to a side of the package, wherein an identification mark associated with the package is etched into the layer to provide a visible identification of the package; and
a substrate electrically or physically coupled with the package.

13. The system of claim 12, wherein the layer is an electromagnetic interference (EMI) shielding layer to protect the package from EMI.

14. The system of claim 12, wherein the side of the package includes silicon or a molding compound.

15. The system of claim 12, wherein the layer is a laminated sheet applied to the side of the package.

16. The system of claim 15, wherein an adhesive material is positioned between the side of the package and the layer to secure the layer onto the package.

17. The system of claim 15, wherein the layer is a metal-filled film.

18. The system of claim 15, wherein the layer includes a polymer resin matrix or acrylic, wherein the layer includes EMI-blocking material within the matrix or acrylic that includes a selected one of silver, copper, or graphite.

19. The system of claim 12, wherein the layer is sprayed or sputtered onto the side of the package.

20. The system of claim 19, further including an adhesive material position between the side of the package and the layer.

21. A method comprising:
applying an electromagnetic interference (EMI) shielding layer to a side of a package; and
laser etching the EMI shielding layer with an identification mark associated with the package to provide visible identification of the package.

22. The method of claim 21, further comprising applying an adhesive layer to the side of the package prior to applying the EMI shielding layer to secure the shielding layer onto the package.

23. The method of claim 21, wherein applying an EMI shielding layer further includes applying a laminated sheet, or spraying or sputtering the layer onto the side of the package.

24. The method of claim 21, wherein the EMI shielding layer includes a polymer resin matrix or an acrylic.

25. The method of claim 21, wherein the EMI shielding layer includes a selected one of silver, copper, or graphite.
